(19) United States
(12) Patent Application Publication
(10) Pub. No.: US 2011/0212272 A1
(43) Pub. Date: Sep. 1, 2011

(54) MANUFACTURING METHOD FOR MAGNETIC RECORDING MEDIUM

(75) Inventors: Tsutomu NISHIHASHI, Chigasaki-shi (JP); Kazuhiro Watanabe, Susono-shi (JP); Tadashi Morita, Tsukuba-shi (JP); Kenji Sato, Kawasaki-shi (JP); Tsutomu Tanaka, Kawasaki-shi (JP); Takuya Uzumaki, Kawasaki-shi (JP)

(73) Assignee: ULVAC, INC., Chigasaki-shi (JP)

(21) Appl. No.: 13/049,250

(22) Filed: Mar. 16, 2011

Related U.S. Application Data
(63) Continuation of application No. PCT/JP09/66234, filed on Sep. 17, 2009.

(30) Foreign Application Priority Data
Sep. 19, 2008 (JP) 2008-241355

(51) Int. Cl. C23C 14/04

(52) U.S. Cl. 427/526

(57) ABSTRACT

A magnetic recording medium having a high magnetic pattern contrast is manufactured. By changing an acceleration voltage that accelerates ions in a process gas, depths (peak depths D₀ and D₁) from a magnetic layer 44, at which an injection amount of a target element is the maximum, can be made with set depths even if a film thickness of an ion permeation portion 48, which is a thin film portion of a resist 49, decreases. Since the set depths are achieved for the peak depths D₀ and D₁, a portion to be processed 43 of the magnetic film 44 is made non-magnetized from a top surface to a bottom surface, and a magnetic portion is separated; thus, the magnetic recording medium with a high magnetic pattern contrast can be obtained.

This application is a continuation of International Application No. PCT/JP2009/066234, filed on Sep. 17, 2009, which claims priority to Japan Patent Application No. 2008-241355, filed on Sep. 19, 2008. The contents of the prior applications are herein incorporated by reference in their entireties.

### BACKGROUND

The present invention generally relates to a manufacturing method of magnetic recording media (such as, hard disks).

There have been known DTR (Discrete Track Recording media) and BPM (Bit Patterned Media) as hard disk magnetic recording media; and more particularly, the BPM on which a plurality of magnetic films is dispersed in a pitted manner has been expected as a next-generation high-density recording medium.

For the magnetic films of such magnetic recording media as discussed above, bit formation by patterning using an etching process has been proposed until now. Since a magnetic head floats above a surface of the magnetic recording medium when recording or reproducing data, surface smoothness is required. Thus, after patterning, a smoothing process is required in which spaces between the magnetic films are filled with a non-magnetic material.

There has been known a method in which an object to be processed having a resist layer disposed on the magnetic film is irradiated with ions (ion beams) of a process gas in order to eliminate the smoothing process and to simplify manufacturing processes (see, JPA 2002-288813 and JPA 2008-77756).

Although a portion of the magnetic film covered with the resist layer is protected from non-magnetization, a target element that is a constituent atom of the process gas is injected in a portion to be processed where the resist layer is not disposed; and then, the portion becomes non-magnetized. Consequently, the non-magnetized portion is formed on the magnetic film along an opening pattern of the resist layer, and a portion where magnetism remains (magnetic portion) is separated by the non-magnetized portion to be a recording portion of the magnetic recording medium.

In order to make non-magnetize the portion to be processed from a surface to a bottom face, generally, a peak depth is set at which an injection amount of the target element is the maximum in the magnetic film, and the ion beams are irradiated with an acceleration voltage that can achieve the set peak depth.

However, when a resist is formed with an original sheet (stamper) or the like, a thin film of the resist also remains on the portion to be processed; and when the thin film is etched by the ion beams, the peak depth moves to a bottom face side even though the acceleration voltage is constant. When the peak depth moves to the bottom face side, a surface portion of the magnetic film and its vicinity are not sufficiently made non-magnetized; and thus, the magnetic portion is not separated. When the magnetic portion is not separated, a phenomenon called “writing blur” occurs in the writing information.

### SUMMARY OF THE INVENTION

In order to solve the above-described problems, the present invention provides a manufacturing method of a magnetic recording medium for making non-magnetize a portion to be processed, by arranging a resist that includes an ion shielding portion and an ion permeation portion having a film thickness thinner than that of the ion shielding portion on a magnetic film of an object to be processed having a substrate and the magnetic film arranged on a surface of the substrate; and injecting the constituent element of a process gas in the portion to be processed where the ion permeation portion of the magnetic film is located in order to make non-magnetize, by accelerating ion of the process gas and by permeating a constitute element of the process gas through the ion permeation portion, wherein the constituent element of the process gas is injected by changing an acceleration voltage that accelerates the ions of the process gas so as to make non-magnetize the portion to be processed.

The present invention is the manufacturing method of a magnetic recording medium, wherein the acceleration voltage is changed in response to the change of the film thickness of the ion permeation portion in such a manner that a depth, from the surface of the magnetic film of which an injection amount of the constituent element is the maximum, is constant.

The present invention is the manufacturing method of a magnetic recording medium, wherein the acceleration voltage is changed in such a manner that a depth, from the surface of the magnetic film of which an injection amount of the constituent element is the maximum, moves.

The present invention is the manufacturing method of a magnetic recording medium, wherein the acceleration voltage is changed in a such manner that a depth from the surface of the magnetic film of which an injection amount of the constituent element is the maximum moves from the side of the substrate to the side of the resist.

The present invention is the manufacturing method of a magnetic recording medium, wherein the acceleration voltage is changed in such a manner that a depth, from the surface of the magnetic film of which an injection amount of the constituent element is the maximum, moves from the side of the resist to the side of the substrate.

Since a peak depth at which the injection amount of the target element is the maximum can be made a set depth by changing the acceleration voltage, it is possible to uniformly make non-magnetize the magnetic film from the surface to the bottom face thereof. Because the magnetic portion (recording portion) is separated where read/write of information are performed, magnetic pattern contrast is good; and thus, the so-called writing blur does not occur.

### BRIEF DESCRIPTION OF THE DRAWINGS

FIG. 1 is a sectional view showing one example of a manufacturing apparatus used for the present invention.

FIGS. 2(a) to 2(c) are sectional views schematically showing non-magnetization processes.

FIG. 3 is a sectional view showing one example of a magnetic recording medium.

### DETAILED DESCRIPTION OF THE INVENTION

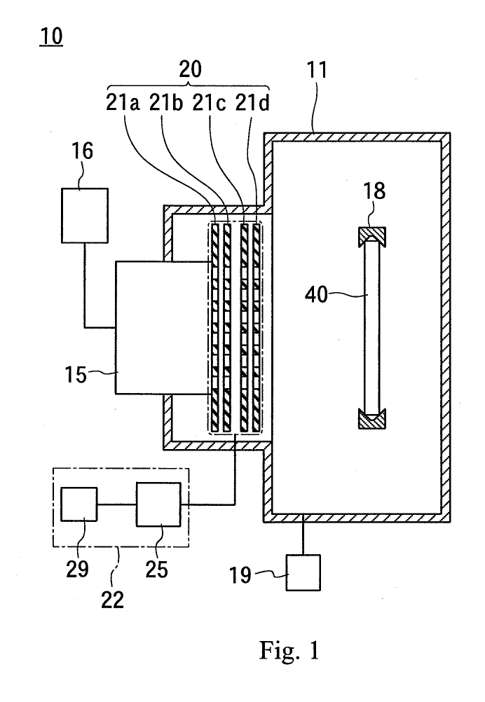

Reference numeral 10 in FIG. 1 denotes one example of a manufacturing apparatus used for the present invention.

This manufacturing apparatus 10 has a vacuum chamber 11 and an ion generator 15.

An internal space of the ion generator 15 is connected to the internal space of the vacuum chamber 11 through an emission port (not shown). A gas supply system 16 is connected to the ion generator 15; and a vacuum evacuation system 19 is connected to the vacuum chamber 11.

When an inside of the vacuum chamber 11 is vacuum-evacuated by the vacuum evacuation system 19, and a process gas (such as, an N₂ gas, for example) is supplied into the ion generator 15 from the gas supply system 16, and a high frequency antenna (not shown) in the ion generator 15 is energized, the process gas ionizes within the ion generator 15, and ions of the process gas charged positively or negatively are generated.

An accelerator 20 is disposed at a position facing the emission port inside the vacuum chamber 11. The accelerator 20 has one or more acceleration electrodes 21a to 21d; and each acceleration electrodes 21a to 21d is arranged along a direction in which the ions of the process gas are emitted.

Through-holes are formed in the acceleration electrodes 21a to 21d, respectively, and the ions of the process gas pass through in the accelerator 20 (through through-holes of the respective acceleration electrodes 21a to 21d, and in spaces between the acceleration electrodes 21a to 21d).

The acceleration electrodes 21a to 21d are connected to an acceleration power supply device 22. The acceleration power supply device 22 has a controller 29 and a power supply source 25; and the power supply source 25 applies voltages with different polarity or magnitude as the acceleration voltages to the acceleration electrodes 21a to 21d adjacent to each other. Since the ions of the process gas are charged, they are accelerated by an acceleration electric field while passing through in the accelerator 20; and then, they are emitted to the inside of the vacuum chamber 11.

The power supply source 25 is connected to the controller 29. The controller 29 is configured so as to change the acceleration voltage applied to the accelerator 20 from the power supply source 25 based on set information, and to thereby be able to change accelerating energy of the ions of the process gas.

Next, processes of manufacturing a magnetic recording medium will be described.

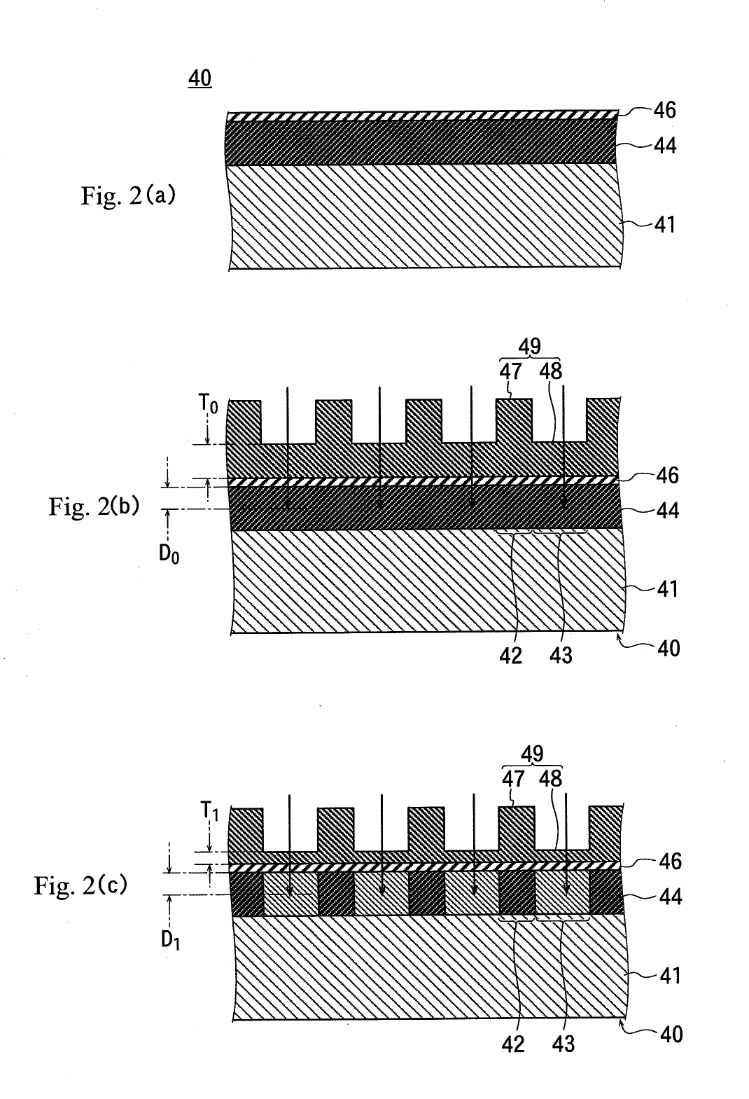

Reference numeral 40 in FIG. 2(a) denotes an object to be processed. The object to be processed 40 has a substrate 41, a magnetic film 44 formed on one surface or both surfaces of the substrate 41, and a protection film 46 formed on a surface of the magnetic film 44. It is to be noted that a foundation film may be provided between the substrate 41 and the magnetic film 44.

In the magnetic film 44, a portion to be processed 43 that is made non-magnetized, and a portion not to be processed 42 that remains without non-magnetization process are predetermined. A resist 49 is transferred on the magnetic film 44 using a stamper; an ion shielding portion 47 formed of a thick film portion of the resist 49 for shielding the ions is disposed on the portion not to be processed 42; and an ion permeation portion 48 formed of a thin film portion thinner than the ion shielding portion 47 of the resist 49 for making the ions permeate is disposed on the portion to be processed 43 (see, FIG. 2(b)).

A film thickness of the magnetic film 44 has been determined, and there can be found energy for injecting a target element required for making non-magnetize the portion to be processed 43 due to the film thickness of the magnetic film 44, and a thickness and an area of the ion permeation portion 48 on the portion to be processed 43. An injection amount of the ions for making non-magnetize the portion to be processed 43 is determined from a relationship calculated in advance between an amount of magnetic property change of the magnetic film 44 and an injection amount of the ions.

When the ions are injected into the ion permeation portion 48 and the ion shielding portion 47, film thicknesses of the ion permeation portion 48 and the ion shielding portion 47 are decreased in accordance with ion energy and an ion incidence time period (ion injection time period). The injection amount of the target element required to make non-magnetize the portion to be processed 43 has been found; and thus, in advance, a decreased amount of the film thickness of the ion permeation portion 48 is calculated at the time of injecting the required amount.

Reference numerals T₀ and T₁ in FIGS. 2(b) and 2(c) denote film thicknesses of the ion permeation portion 48, the reference numeral T₀ denotes an initial film thickness at the time of starting non-magnetization process before being etched by the ions of the process gas, and the reference numeral T₁ denotes a last film thickness at the time of completing the non-magnetization process in which the required amount of the target element is injected.

When a depth from the surface of the magnetic film 44 to a position at which the injection amount of the target element is the maximum, defined as a “peak depth”, the peak depth can be changed in a range where zero is the lower limit and the distance equal to the film thickness of the magnetic film 44 is the upper limit.

Reference numerals D₀ and D₁ in FIGS. 2(b) and 2(c) denote an initial peak depth that is a peak depth at the time of starting non-magnetization, and a last peak depth that is a peak depth at the time of completing the injection of a required amount of the target element. There are the following cases: where the initial peak depth D₀ and the last peak depth D₁ are equal to each other, and thus the peak depth is constant; where the initial peak depth D₀ is larger than the last peak depth D₁, and a position of the peak depth moves from a substrate 41 side to a resist 49 side in accordance with an elapsed time of ion injection; and where the initial peak depth D₀ is smaller than the last peak depth D₁, and the position of the peak depth moves from the resist 49 side to the substrate 41 side in accordance with the elapsed time of ion injection.

Calculated are an initial acceleration voltage V₀ that can achieve the initial peak depth D₀ when the film thickness of the ion permeation portion 48 is the initial film thickness T₀, and a last acceleration voltage V₁ that can achieve the last peak depth D₁ when the film thickness of the ion permeation portion 48 is the last film thickness T₁, and then they are set in the controller 29.

A vacuum ambience is formed in the vacuum chamber 11; the object to be processed 40 in a state of FIG. 2(b) is held by a holder 18 for holding the substrate so as to be carried in the vacuum chamber 11; and the surface where the resist 49 has been disposed is made to face the accelerator 20 (FIG. 1). Ions of the process gas are generated in a state where the vacuum ambience in the vacuum chamber 11 is maintained; and the vacuum chamber 11 is set at the ground potential.

The controller 29 starts a non-magnetization process by applying the initial acceleration voltage V₀ to the accelerator 2, changes the acceleration voltage at least one time until injection of the required amount of target element is completed, brings the acceleration voltage closer to the last acceleration voltage V₁, applies the last acceleration voltage V₁ when the injection of the required amount of target element is completed, and then completes the non-magnetization process. During the non-magnetization process, the acceleration voltage may be gradually reduced or may be continuously reduced.

When the peak depth moves from the resist 49 side to the substrate 41 side (D₀<D₁), the acceleration voltage is increased so as to achieve a depth equal to an injection depth, corresponding to a decreased amount of the resist film or more.

When the lost film thickness of the resist film (amount of decreased film) caused by the ion injection is increased, a distance from the surface of the resist 49 to the peak depth becomes short and a position of the peak depth from the surface of the resist film becomes shallow, so that when the peak depth from the surface of the magnetic film 44 is made constant (D₀=D₁), the acceleration voltage is reduced in response to the increase of the amount of decreased film so as to make the peak depth constant.

When a rate of decrease of the film amount (decreased amount of the film per time) is constant, a rate of reducing the acceleration voltage (a reducing value of the acceleration voltage per time) indicates a value corresponding to the decreased amount of the film, and it is constant. However, when the peak depth is moved from a bottom face side of the magnetic film 44 (substrate 41 side) to a surface side of the magnetic film 44 (D₀>D₁), it is necessary to reduce the acceleration voltage at a higher rate than the reduction rate of the acceleration voltage at the time of making the peak depth constant.

Conversely, when the peak depth is moved from the resist 49 side to the substrate 41 side (D₀<D₁), the acceleration voltage is increased so as to achieve the depth equal to the injection depth corresponding to the decreased amount of the resist film, or more.

In other words, when the peak depth is moved from the resist 49 side to the substrate 41 side (D₀<D₁), the reducing rate of the acceleration voltage can be made constant or smaller than the reducing rate of the acceleration voltage at the time of making the peak depth constant. Furthermore, the acceleration voltage can be increased in accordance with the elapsed time of the ion injection. It is preferable that the acceleration voltage fall in a range where the peak depth does not exceed the film thickness of the magnetic film 44.

When the peak depths D₀ and D₁ are made constant, if the peak depths D₀ and D₁ are set in the center of the magnetic film 44 in a film thickness direction thereof, efficiency of non-magnetization is the highest. When the peak depth D₀ from the surface of the magnetic film 44 and the peak depth D₁ from the surface of the magnetic film 44 are made different, a region in which the target element is injected moves from the surface to the bottom face of the magnetic film 44.

It is to be noted that the peak depths D₀ and D₁ from the surface of the magnetic film 44 may be changed from increase to decrease or from decrease to increase in the middle of the non-magnetization process. In this case, an acceleration voltage that can achieve the set peak depth is examined; and it is then set in the controller 29 not only at the time of the start and at the time of the completion of the non-magnetization process, but in the middle of the non-magnetization process.

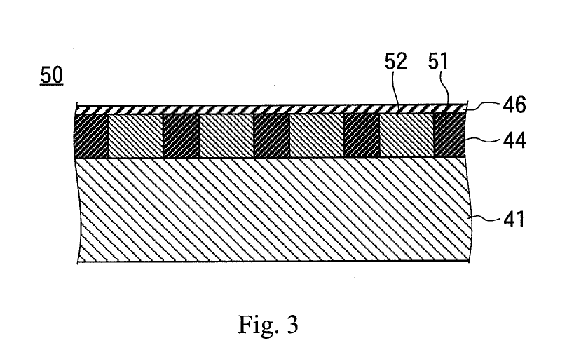

After completing the non-magnetization process, application of the acceleration voltage is stopped, or the object to be processed 40 is covered by a shutter etc. to thereby stop irradiating the object to be processed 40 with the ions of the process gas. The object to be processed 40 is carried out from the vacuum chamber 11, and the resist 49 is removed. If it is necessary, a lubrication layer or another layer is formed on the protection film 46 by forming a new protection film after removing the protection film 46 or by growing the protection film 46 in order to increase the film thickness thereof, thereby a magnetic recording medium 50 is obtained (FIG. 3).

Ion injection into the portion not to be processed 42 is not performed since the ion shielding portion 47 is located at an upper part thereof; and reference numeral 51 in FIG. 3 denotes a magnetic portion consisting of the portion not to be processed 42 that has been prevented from becoming non-magnetized. Reference numeral 52 in FIG. 3 denotes a nonmagnetic portion consisting of the portion to be processed 43 which is non-magnetized. The magnetic portion 51 is divided into a plurality of portions by the nonmagnetic portion 52, and each divided magnetic portion 51 becomes a recording portion where read/write information is performed.

Although there has been described above the case where the magnetic film 44 is formed on one side of the substrate 41, the present invention is not limited to this case, and the magnetic film 44 may be formed on both sides of the substrate 41. In such a case, both sides may be non-magnetized simultaneously, or they may be non-magnetized one by one.

It is preferable that the target element be, for example, at least one element selected from a group of O, B, P, F, N, H, C, Kr, Ar and Xe. Two or more kinds of atoms, as described above, may be injected. For the process gas, a gas is used that contains one or more target element(s), as described above, in a chemical structure thereof.

A structure of the magnetic film 44 is not particularly limited as long as it contains magnetic materials (such as, Fe, Co and Ni). For example, an artificial lattice film (metal laminated film such as, Co/Pd, Co/Pt, Fe/Pd, and Fe/Pt) or a CoPt (Cr) alloy can be used. In addition, in a case of an in-plane magnetic recording type magnetic film 44, for example, a film formed by laminating a nonmagnetic CrMo foundation layer and a ferromagnetic CoCrPtTa magnetic layer can be used.

Although a film thickness of the ion shielding portion 47 is not particularly limited, it is made thick such that the target element may not reach the portion not to be processed from the start to the completion of a non-magnetization process. The ion permeation portion 48 is made thin such that the target element can permeate it to reach the portion to be processed.

Although the protection film 46 is not particularly limited, it can be made of, for example, at least one protection material (s) selected from a group of carbon (such as, DLC (diamond like carbon)), hydrogenated carbon, nitrogenated carbon, silicon carbide (SiC), SiO₂, Zr₂O₃, and TiN.

Although the stamper is not particularly limited, it is, for example, formed in a plate-shape in which a concave portion having a plane shape substantially equal to the shape of the portion not to be processed 42 is formed on the surface thereof at the same interval as the portion not to be processed 42.

A method for forming the resist 49 using the stamper will be described hereinafter. The resist 49 is held and pressed between the stamper and the object to be processed 40. The resist 49, when containing thermoplastic resin, is heated while pressed.

Since the resist 49 is pressed to be pushed away from a top of a convex portion, and then flows into a concave portion, the ion shielding portion 47 made of a thick film of the resist 49 is formed on the portion not to be processed 42. The resist 49 is not thoroughly pushed away from the top of the convex portion, but a part thereof remains as it is; and thus, the ion permeation portion 48 made of a thin film of the resist 49 is formed on the portion to be processed 43.

The resist 49 is, when containing thermosetting resin (such as, epoxy resin), hardened by heating, when containing ultraviolet curable resin (such as, acrylate) hardened by ultraviolet irradiation, and when containing thermoplastic resin, solidified by cooling.

Adhesive property of a surface of the stamper to the hardened (or solidified) resist 49 is made lower than the adhesive property of the resist 49 to the object to be processed 40; and when the stamper is removed, the resist 49 on which the ion shielding portion 47 and the ion permeation portion 48 have been formed remains on the object to be processed 40.

In a photolithographic method, which instead of using the stamper, has the resist 49 on the portion to be processed 43 etched halfway to form the ion permeation portion 48, and has the resist 49 on the portion not to be processed 42 made to remain without etching process to form the ion shielding portion 47. However, when using the stamper rather than the photolithographic method, manufacturing processes are simpler, and less amount of materials (such as, the resist 49 and an etchant) is needed so that it is economical.

The substrate 41 is not particularly limited as long as it is nonmagnetic and, for example, a glass substrate, a resin substrate, a ceramic substrate, an aluminum substrate or the like can be used.

A manufacturing method of the present invention is widely applicable to a manufacturing method of magnetic recording media in which a part of a magnetic film is non-magnetized to separate a plurality of magnetic portions; and specifically, it can be used for manufacturing a variety of magnetic recording media, such as DTR (Discrete Track Recording media) and BPM (Bit Patterned Media).

What is claimed is:

1. A manufacturing method for a magnetic recording medium, comprising steps of:
arranging a resist that includes an ion shielding portion and an ion permeation portion having a film thickness thinner than the thickness of the ion shielding portion on a magnetic film of an object to be processed having a substrate and the magnetic film arranged on a surface of the substrate; and
injecting the constituent element of a process gas in the portion to be processed where the ion permeation portion of the magnetic film is located in order to become non-magnetize, by accelerating ion of the process gas and by permeating a constituent element of the process gas through the ion permeation portion,
wherein the constituent element of the process gas is injected by changing an acceleration voltage that accelerates the ions of the process gas so as to make non-magnetize the portion to be processed.

2. The manufacturing method for a magnetic recording medium according to claim 1, wherein the acceleration voltage is changed in response to the change of the film thickness of the ion permeation portion in such a manner that a depth, from the surface of the magnetic film of which an injection amount of the constituent element is the maximum, is constant.

3. The manufacturing method for a magnetic recording medium according to claim 1, wherein the acceleration voltage is changed in such a manner that a depth, from the surface of the magnetic film of which an injection amount of the constituent element is the maximum, moves.

4. The manufacturing method for a magnetic recording medium according to claim 3, wherein the acceleration voltage is changed in such manner that a depth, from the surface of the magnetic film of which an injection amount of the constituent element is the maximum, moves from the side of the substrate to the side of the resist.

5. The manufacturing method for a magnetic recording medium according to claim 3, wherein the acceleration voltage is changed in such a manner that a depth, from the surface of the magnetic film of which an injection amount of the constituent element is the maximum, moves from the side of the resist to the side of the substrate.
